(19) United States
(12) Patent Application Publication
(10) Pub. No.: US 2013/0105087 A1
(43) Pub. Date: May 2, 2013

(54) SOLAR WAFER ELECTROSTATIC CHUCK

(71) Applicant: Intevac, Inc., Santa Clara, CA (US)

(72) Inventors: Young Kyu Cho, San Jose, CA (US); Karthik Janakiraman, San Jose, CA (US); Terry Bluck, Santa Clara, CA (US); Diwakar Kedlaya, San Jose, CA (US)

(73) Assignee: INTEVAC, INC., Santa Clara, CA (US)

(21) Appl. No.: 13/666,917

(22) Filed: Nov. 1, 2012

Related U.S. Application Data
(60) Provisional application No. 61/554,457, filed on Nov. 1, 2011.

(51) Int. Cl. H02N 13/00; H01L 31/18

(52) U.S. Cl. CPC H02N 13/00; H01L 31/18
USPC 156/345.43; 361/234; 118/723 E; 156/345.44; 29/825

(57) ABSTRACT

An electrostatic chuck is disclosed, which is especially suitable for fabrication of substrates at high throughput. The disclosed chuck may be used for fabricating large substrates or several smaller substrates simultaneously. For example, disclosed embodiments can be used for fabrication of multiple solar cells simultaneously, providing high throughput. An electrostatic chuck body is constructed using aluminum body having sufficient thermal mass to control temperature rise of the chuck, and anodizing the top surface of the body. A ceramic frame is provided around the chuck's body to protect it from plasma corrosion. If needed, conductive contacts are provided to apply voltage bias to the wafer. The contacts are exposed through the anodization.

### RELATED APPLICATION

This application claims priority benefit from U.S. Provisional Application Ser. No. 61/554,457, filed on Nov. 1, 2011, the content of which is incorporated herein by reference in its entirety.

### BACKGROUND

1. Field

This disclosure relates to processing of solar cells and, in particular, to electrostatic chucks supporting wafers inside solar cells processing chambers.

2. Related Art

Processing chambers, such as plasma chambers, used to fabricate solar cells have the same basic elements of processing chambers used for fabricating integrated circuits (IC), but have different engineering and economic requirements. For example, while chambers used to fabricate integrated circuits have throughput on the order of a few tens of wafers per hour, chambers used for fabricating solar are required to have throughput on the order of a few thousands of wafers per hour. On the other hand, the cost of purchasing and operating a solar cell processing system must be very low.

Processing systems used for both IC and solar cell fabrication utilize electrostatic chucks to support the wafers during processing. However, the electrostatic chuck for solar cell system must cost a fraction of that for an IC manufacturing, yet it must endure much higher utilization rate due to a much higher throughput of the solar cell fabrication system. Moreover, while in IC systems the electrostatic chuck is stationary, in some solar cell fabrication systems the chuck is movable. Consequently, no connections for cooling fluid can be made, such that active thermal control of the chuck is not possible.

Various steps involved in the fabrication of solar cells require exposure of the wafer to plasma. During certain processing steps, the plasma is formed using corrosive gases, which attack any exposed part of the chuck supporting the wafers. Therefore, another requirement on the chuck is to be able to withstand such corrosive attacks of the plasma.

Accordingly, what is needed in the art is an electrostatic chuck that is inexpensive to manufacture, can endure high utilization rates without active cooling, and can withstand corrosive effects of plasma.

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

An electrostatic chuck is disclosed, which is especially suitable for fabrication of substrates at high throughput. The disclosed chuck may be used for fabricating one substrate at a time or simultaneously fabricating several substrates positioned on several chucks. For example, disclosed embodiments can be used for fabrication of multiple solar cells simultaneously, providing high throughput.

Various embodiments provide an electrostatic chuck which is designed to endure high throughput processing, such as that used in solar fabrication systems, and can withstand corrosive plasmas. Disclosed embodiments take advantage of static mass and processing cycles to thermally control the chuck, and dispense with active fluid cooling.

According to disclosed embodiments, an electrostatic chuck body is constructed using aluminum having sufficient thermal mass to control temperature rise of the chuck. The top surface of the aluminum body is anodized to provide endurance to high utilization rates. A ceramic frame is provided around the chuck's body to protect it from plasma corrosion. If needed, conductive contacts are provided to apply voltage bias to the wafer. The contacts are exposed through the anodization.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1A is a schematic illustrating the major parts of an electrostatic chuck according to one embodiment, while FIG. 1B illustrates a partial cross-section along line A-A of FIG. 1A.

FIG. 1C is a flow chart illustrating a process flow for fabricating the chuck illustrated in FIGS. 1A and 1B.

FIG. 2 illustrates an example of a plasma chamber for processing substrates, utilizing a chuck according to an embodiment of the invention.

FIG. 3A is a schematic illustrating the major parts of an electrostatic chuck according to another embodiment, while FIG. 3B illustrates a partial cross-section along line A-A of FIG. 3A.

FIG. 4A is a schematic illustrating the major parts of an electrostatic chuck according to yet another embodiment, while FIG. 4B illustrates a partial cross-section along line A-A of FIG. 4A.

FIGS. 5A is a schematic illustrating the major parts of an electrostatic chuck according to yet another embodiment, while FIG. 5B illustrates a partial cross-section along line A-A of FIG. 5A.

FIG. 6 is a schematic illustrating the major parts of an electrostatic chuck and carrier according to one embodiment of the invention.

### DETAILED DESCRIPTION

Various features of the electrostatic chuck according to embodiments of the invention will now be described with reference to the drawings. The description will include examples of electrostatic chuck, processing systems incorporating the electrostatic chuck, and methods for making the electrostatic chuck for fabrication of, e.g., solar cells.

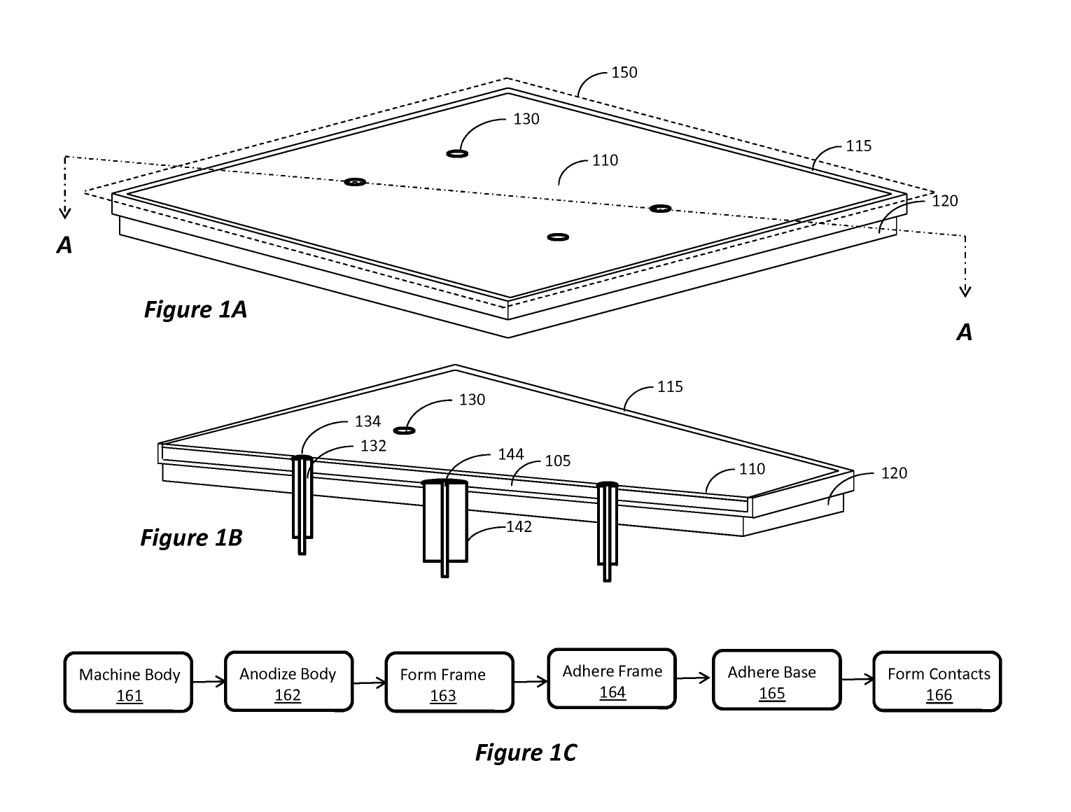

FIG. 1A is a schematic illustrating the major parts of an electrostatic chuck according to one embodiment, while FIG. 1B illustrates a partial cross-section along line A-A of FIG. 1A. The chucks body 105 is made of aluminum slab and is configured to have sufficient thermal mass to control heating of the chuck during plasma processing. The top surface of the body 105 is anodized, thereby forming electrically insulating anodized aluminum layer 110. The sides of the chuck are encased by ceramic layer or frame 115. Ceramic layer 115 may be a ceramic coating applied to all four sides of the aluminum body, e.g, using standard plasma spray coating or other conventional methods. In the embodiment shown in FIGS. 1A and 1B, the aluminum body 105 is placed inside a ceramic “tub” such that all four sides and the bottom of the aluminum body 105 are covered by a ceramic frame 115. The body 105 is bonded to the ceramic frame 115. The top of the ceramic frame 115 is level with the top of the anodized aluminum layer 110. Also, the chuck is sized so that the chucked wafer extends beyond the ceramic sides 115, so as to cover the top of the ceramic sides 115. This is illustrated by the broken-line outline of wafer 150 in FIG. 1A.

The chuck is attached to a base 120, which may be made of an insulative or conductive material. An aperture is formed through the base 120 and an insulating sleeve 142 is positioned therein. A conductor contact rod 144 is passed through the insulating sleeve 142 so as to form electrical contact to the aluminum body 105. Conductor rod 144 is used to conduct high voltage potential to form the chucking force to chuck the wafers.

In some processing chambers it is necessary to bias the processed wafers so as to attract ions from the plasma towards the wafers. For such processing, the chuck is provided with contact points 130 to deliver voltage bias to the wafers. Each contact point 130 is formed by an insulating sleeve 132, which passes through the base 120 and though the body 105. A contact rod 134, which may be spring biased or retractable (not shown), passes through the insulating sleeve 132.

The protective ceramic frame 115 may be made of materials such as, e.g., alumina (aluminum oxide), SiC (silicon carbide), silicon nitride (Si₃N₄), etc. The selection of ceramic material depends on the gasses within the plasma and on potential contamination of the processed wafers.

The arrangement illustrated in FIGS. 1A and 1B provides certain advantages over prior art chucks. For example, due to its simple design, it is inexpensive to manufacture. Also, the anodized surface can endure repeated processing, while the ceramic frame protects the anodization and the chuck's body from plasma corrosion. Since the ceramic frame is designed to be slightly smaller than the chucked wafer, the ceramic frame is sealed by the chucked wafer, thereby preventing plasma attack on the edges of the chuck/ceramic frame.

FIG. 1C is a flow chart illustrating a process flow for fabricating the chuck illustrated in FIGS. 1A and 1B. In step 161 an aluminum block is machined to form the chuck's body 105. In step 162 the top surface of the aluminum body is anodized using standard anodization process. In step 163 ceramic frame 115 is fabricated and in step 164 the aluminum body 105 is bonded to the ceramic frame 115. In step 165 the assembly of the body and frame is bonded to a base 120. In step 166 the various electrical contacts and insulation sleeves are attached to the chuck.

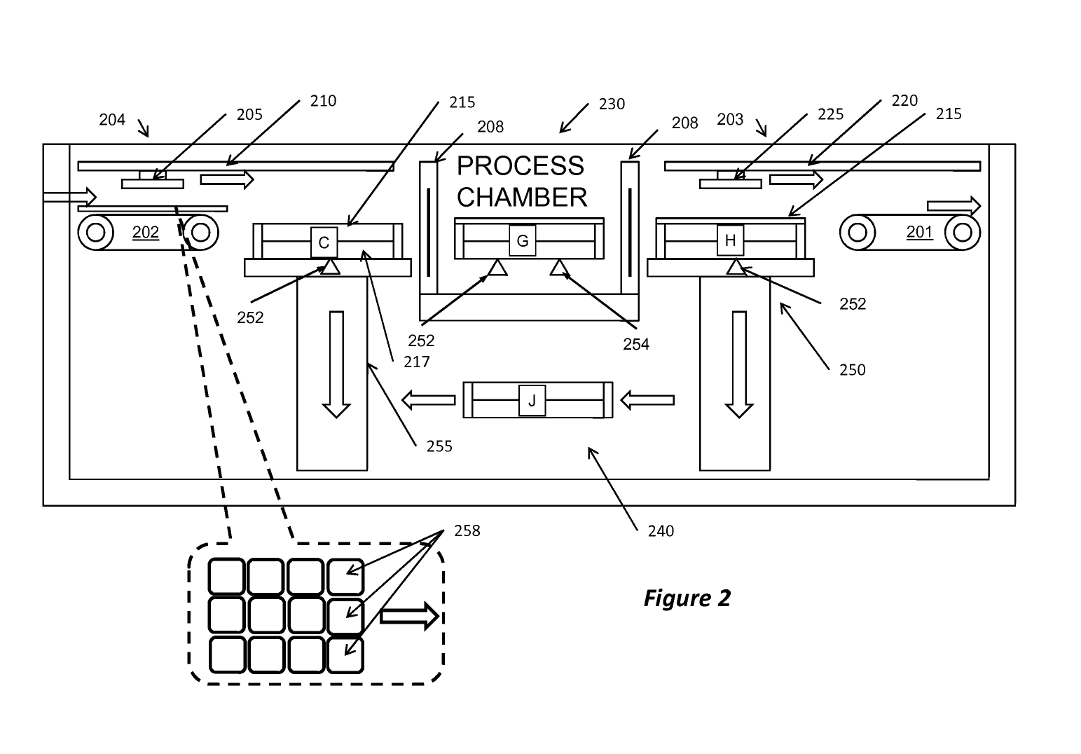

FIG. 2 illustrates a schematic cross-section of one example of plasma system utilizing the chuck illustrated in FIGS. 1A and 1B. Since FIG. 2 is provided in order to provide an example of the use of the transportable electrostatic chuck, various elements not relating to that function are omitted. The processing chamber 230 shown in FIG. 2 may be any plasma processing chamber, such as etch, PECVD, PVD, etc.

The following is an example of a processes sequence using the embodiment of FIG. 2. The wafers 258 are delivered to the system on an incoming conveyor 202. In this example, several wafers 258 are placed abreast in the direction orthogonal to the conveyor's travel direction. For example, three wafers 258 can be arranged in parallel, as shown in the callout, which is a top view of the substrates on the conveyor, with the arrow showing the direction of travel.

A wafer transport mechanism 204 is used to transport the wafers 258 from the conveyor 202 onto the processing chucks 215. In this example, the transport mechanism 204 employs an electrostatic pickup chuck 205, which is movable along tracks 210 and uses electrostatic force to pick up one or more wafers, e.g., one row of three wafers, and transfer the wafers to the processing chucks 215. In this example, three processing chucks 215 are used to receive the three substrates held by the pickup chuck 205. As shown in FIG. 2, the loading of wafers onto the processing chucks 215 is done at the loading station C. The processing chucks 215 are attached to carriers 217, which are transported into the first processing chamber 230 via shutter 208.

The process chamber is isolated from the loading station and other chambers by shutter 208. Shutter 208 greatly reduce conductance to adjacent chambers, allowing for individual pressure and gas control within the process chambers without vacuum valves and o-ring seals. In this example only a single processing chamber 230 is used. However, as can be understood, additional chambers can be added serially, such that the substrates will be moving from one chamber directly to the next, via isolation shutters 208 placed between each two chambers (not shown).

Once chuck 215 is positioned inside the processing chamber 230, electrical contact is made to the contact rods 134 and 144, by contacts 252 and 254, to deliver the required voltage potential. Plasma processing then commences and the substrates are processed. Once processing is completed at the last chamber in the series of chambers, the last shutter 208 is opened and the chuck 215 is transported on carrier 217 to the unloading station H.

At the unloading station H, a wafer transport mechanism 203 is used to unload wafers from the chuck 215 and transport the wafers onto unload conveyor 201. Transport mechanism 203 employs an electrostatic wafer pickup head 225, which rides on tracks 220, similar to the pickup chuck 205. The pickup head 225 uses electrostatic forces to transfers wafer from process chucks 215 to outgoing conveyor 201. Outgoing wafer conveyor 201 receives the wafers from the pickup head 225 and conveys them to further processing downstream.

The chucks 215 are then lowered by elevator 250 and are transported by chuck return module 240 to elevator 255, which returns the chucks to station C for receiving another batch of wafers. As can be understood, several processing chucks are used, such that each station is loaded and the processing chamber is always occupied and processing wafers. That is, as one group of chucks leaves the processing chamber into station H, another group from station C is moved into the chamber and a group from elevator 255 is moved into station C. Also, in this embodiment, as the elevators 250 and 255 move chucks between process level and return level, they actively cool the process chuck 215 using, e.g., heat sinks Alternatively, or in addition, cooling station J is used to cool the chucks by contacting the chuck with a heat sink. The process chucks 215 are returned from unload station H to load station C via a return tunnel 240, which is positioned under the process level.

Electrical contacts 252 to the chuck are located on each elevator and in each process chamber for electrostatic chucking of wafers. That is, as explained above, since the chucks are movable, no permanent connections can be made to the chucks. Therefore, in this embodiment, stations C and H and each processing chamber 230 include electrical contacts 252 to transfer electrical potential to the chuck, via contact 144, and enable electrostatic chucking Additionally, DC bias contacts 254 are located in each process chamber 230 for DC bias of wafer if required. That is, for some processing, DC bias is used in addition to plasma RF power, in order to control the ion bombardment from the plasma on the wafer. The DC potential is coupled to the wafers by contacts 134, which receive the DC bias from contacts 254.

Thus, as seen from the above, the system illustrated in FIG. 2 may utilize several process chucks 215, which continuously move from load position C, through a series of process chambers 230, to an unload position H. The process chambers 230 are individually pumped and separated from each other and from the load and unload zones by shutters 208. The shutters provide vacuum and plasma zone separation for each chamber. This allows for individualized gas species and pressure control in each zone. For simplicity, only one processing chamber 230 is illustrated in FIG. 2, but a series of chambers may be connected serially, such that a chuck exiting one chamber directly enters a second chamber.

The chucks return from the unload station H to the load station C via a vacuum tunnel 240, located under the process chambers 230. The chucks recirculate through the system, so they cannot have any fixed connections such as wires, gas lines or cooling lines. Contact for bias and chucking is made at each location the chuck stops in. Chuck cooling is achieved by active cooling on the unload and load elevators 250 and 255, respectively, and/or cooling station J. In this example, when the chuck is cooled it is mechanically clamped against a cooled heat sink.

In the example of FIG. 2, several chucks 215 are present in each process chamber during processing, so that multiple substrates are being plasma processed simultaneously. In this embodiment, the wafers are processed simultaneously by being supported on several individual chucks, e.g., three chucks, situated abreast. In one specific example, each chamber is fabricated to hold one row of three individual chucks, so as to simultaneously process three wafers. Of course, other arrangement may be used, e.g., a two by three array of chucks, etc.

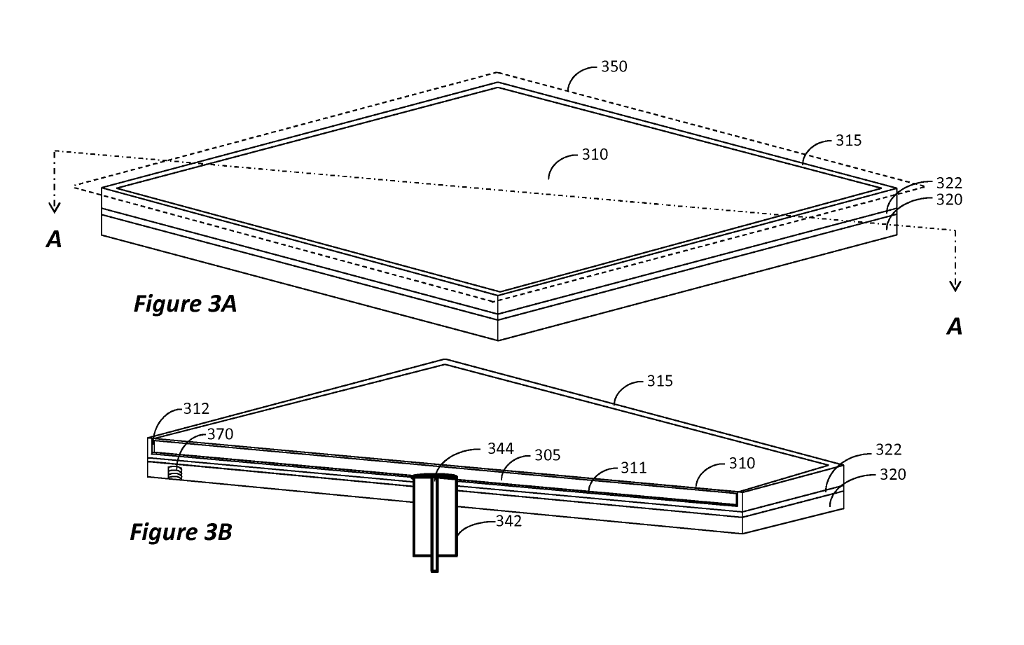

FIG. 3A is a schematic illustrating the major parts of an electrostatic chuck according to another embodiment, while FIG. 3B illustrates a partial cross-section along line A-A of FIG. 3A. Elements in FIGS. 3A and 3B that are similar to those of FIGS. 1A and 1B are indicated with the same reference numerals, except that they are in a different centennial series. As seen in FIG. 3A, No contact are made for directly applying bias to the wafer 350. Instead, capacitive coupling from the plasma to the chuck is relied upon to provide RF path to the chuck and bias to the wafer.

The structure of the electrostatic chuck will now be described with reference to FIG. 3B. The chuck of this embodiment is fabricated by machining an aluminum body 305. All the surfaces of the body 305 are then anodized, to provide a hard insulative surface, shown as top anodization layer 310, bottom anodization layer 311, and side anodization layer 312. The anodized aluminum body is bonded onto a ceramic tub 315 made out of, e.g., alumina, and serving as an insulator and protecting the sides of the anodized aluminum body from plasma corrosion. The ceramic tub is bonded onto an insulating plate 322, made of, e.g., polyimide, Kapton®, etc. The thickness of the insulating plate 322 is determined depending on the dielectric constant of the plate's material, so as to provide the required capacitive coupling of RF power to the base plate 320. Base plate 320 is made of aluminum and is also anodized, and is used to capacitively couple RF from the plasma. The amount of coupling depends, in part, on the properties, such as thickness and dielectric constant, of the insulating plate 322. Also, alternatively, rather than using insulative plate, the bottom plate of tub 315 can be made thicker to provide the same insulating properties. Also, threaded holes 370 are provided to attach the chuck to a carrier, which is described below.

As noted above, the aluminum body 305 is anodized on all sides. Therefore, to make the electrical contact with contact rod 344, the anodization is removed from area of the contact on the bottom of the aluminum body. Additionally, the area where the anodization was removed is plated with a conductive layer such as, e.g., nickel, chromium, etc. When the contact rod 344 is inserted into the insulating sleeve 342, it contacts the plated conductive layer and good electrical contact is then maintained.

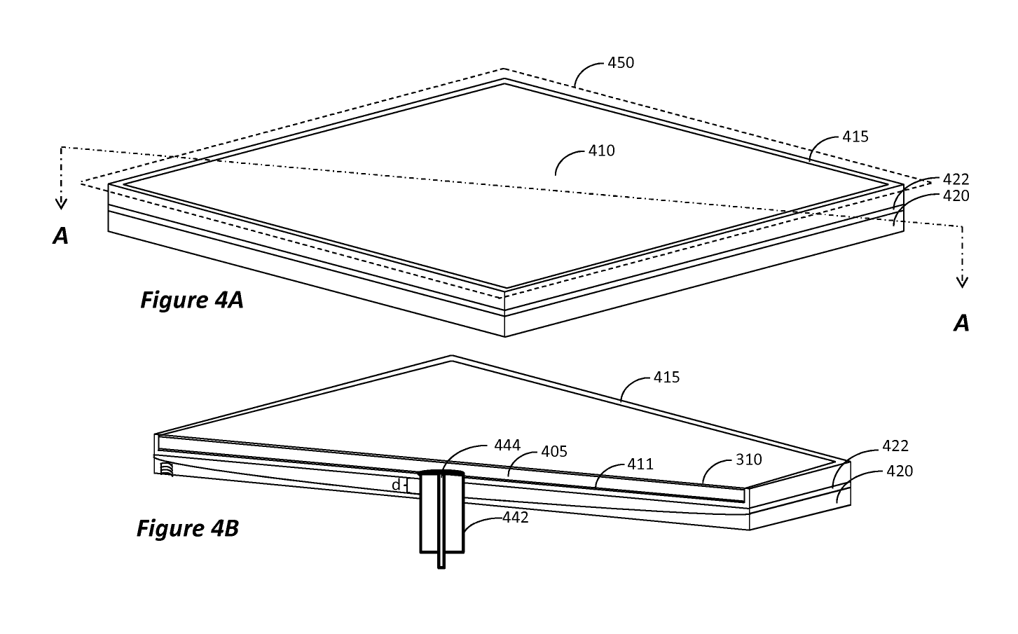

As can be understood from the above, to make the chucks simple, inexpensive, and transportable, no connections for bias power to the wafer and no cooling are provided. Also, unlike semiconductor chucks, wherein the chucked wafer is round, here the wafer is square to comply with solar cell processing. Consequently, the plasma over the wafer can be very non-uniform, leading to a non-uniform processing of the wafer. The embodiment illustrated in FIGS. 4A and 4B is designed to overcome such plasma non-uniformity.

The structure of the chuck illustrated in FIGS. 4A and 4B is similar to that of FIGS. 3A and 3B, and elements in FIGS. 4A and 4B that are similar to those of FIGS. 3A and 3B are indicated with the same reference numerals, except that they are in a different centennial series. However, in order to overcome plasma non-uniformity, in the embodiment of FIGS. 4A and 4B the insulating plate 422 has a non-flat bottom surface, and the top surface of the base plate has a matching surface. In the embodiment of FIGS. 4A and 4B, the bottom surface of the insulating plate 422 is convex, while the top surface of the base plate 420 has a matching concave shape. That is, the insulating plate is thinner at its edges than in its middle. Consequently, less insulation is provided at the edges of the chuck between the body 405 and the base plate 420, such that better RF coupling is achieved at the edges, leading to better plasma uniformity.

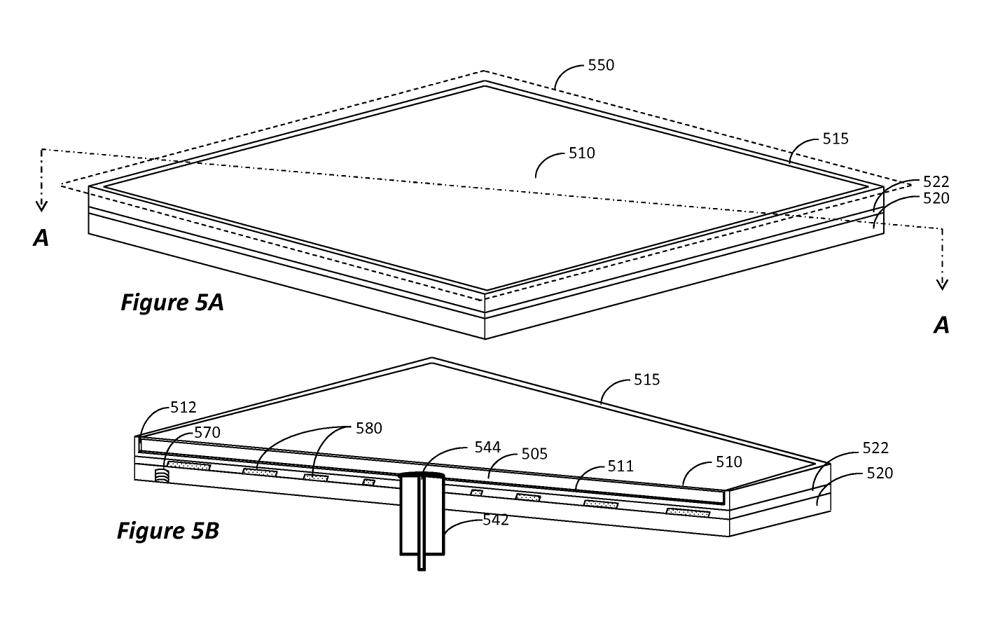

The plasma non-uniformity can be addressed by other means. For example, the insulating plate may be made to have variable dielectric constant, such that it is higher at the center of the plate than at the edges. For example, the insulating plate may be made of a series of rings, each made of different dielectric constant material. An alternative arrangement is illustrated in FIGS. 5A and 5B. Elements in FIGS. 5A and 5B that are similar to those of FIGS. 3A and 3B are indicated with the same reference numerals, except that they are in a different centennial series. As shown in FIG. 5B, a series of trenches 580 are formed on one surface of the insulating plate 522. The trenches reduce the dielectric insulation of the insulation plate 522 and can be filled with lower dielectric material or with conductor, depending on the insulation required. For example, the trenches can be filled with the same adhesive, such as Kapton® or conductive adhesive, used to bond the insulating plate 522 to the base plate 520.

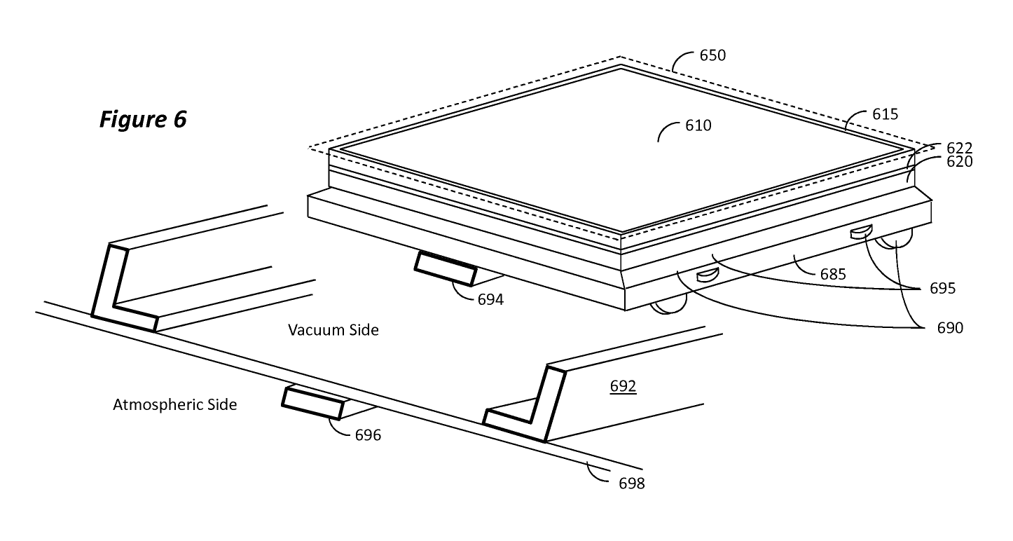

FIG. 6 illustrates an arrangement for utilizing any of the chucks described above in a plasma processing system, such as that illustrated in FIG. 2. Generally, the chuck is connected to a carrier 685, e.g., by bolting the base 620 to the carrier 685. The carrier 685 has one set of vertically-oriented wheels 690 and one set of horizontally oriented wheels 695, which are fitted to ride on rails 692. In this embodiment, motive force is provided by a linear motor which is partially positioned on the carrier in vacuum and partially positioned outside vacuum beyond the vacuum partition 698. For example, a series of permanent magnet 694 can be provided on the bottom of the carrier, while a series of coils 696 are positioned in atmospheric environment outside of partition wall 698.

It should be understood that processes and techniques described herein are not inherently related to any particular apparatus and may be implemented by any suitable combination of components. Further, various types of general purpose devices may be used in accordance with the teachings described herein. The present invention has been described in relation to particular examples, which are intended in all respects to be illustrative rather than restrictive. Those skilled in the art will appreciate that many different combinations will be suitable for practicing the present invention.

Moreover, other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

1. An electrostatic chuck for plasma processing chamber, comprising:
an aluminum chuck body having an anodized top surface;
a ceramic frame provided around and bonded to the aluminum body;
high voltage electrical contacts electrically connected to the aluminum body.

2. The electrostatic chuck of claim 1, further comprising a ceramic plate bonded to bottom surface of the aluminum body.

3. The electrostatic chuck of claim 2, wherein the ceramic plate made is integral with the ceramic frame, thereby forming a tub, and wherein the aluminum body is bonded inside the tub.

4. The electrostatic chuck of claim 3, wherein the top surface of the frame is flush with the anodized top surface.

5. The electrostatic chuck of claim 2, further comprising a base attached to bottom surface of the ceramic plate.

6. The electrostatic chuck of claim 2, further comprising an insulating plate attached to bottom surface of the ceramic plate, and a base attached to bottom surface of the insulating plate.

7. The electrostatic chuck of claim 6, wherein the insulating plate is configured to vary capacitive coupling of RF power to the base.

8. The electrostatic chuck of claim 6, wherein the insulating plate has a non-uniform thickness.

9. The electrostatic chuck of claim 6, wherein the insulating plate is thinner at its edges than at its center.

10. The electrostatic chuck of claim 6, wherein the insulating plate has a plurality of trenches on one surface thereof.

11. The electrostatic chuck of claim 1, wherein the frame is structure to be slightly smaller than a wafer to be processed on the electrostatic chuck.

12. The electrostatic chuck of claim 1, further comprising chucking contacts isolated from the aluminum body and extending through the anodized top surface.

13. The electrostatic chuck of claim 1, wherein the ceramic frame comprises alumina.

14. The plasma processing chamber, comprising:
a chamber enclosure configured to maintain vacuum environment and sustain plasma therein and having a loading port and an unloading port;
a transport mechanism for transporting at least one carrier into the processing enclosure through the loading port and out of the processing enclosure through the unloading port;
a carrier transportable by the transport mechanism, the carrier having an electrostatic chuck attached thereto, the chuck comprising an aluminum body and a ceramic frame bonded to the aluminum body.

15. The plasma processing chamber of claim 14, further comprising a high voltage electrical contact provided inside the chamber and coupling DC voltage to the aluminum body.

16. The plasma processing chamber of claim 15, wherein the aluminum body comprises an anodized top surface.

17. The plasma processing chamber of claim 16, wherein the chuck further comprises chucking contacts electrically insulated from the aluminum body and extending through the anodized surface.

18. The plasma processing chamber of claim 14, wherein the transport mechanism is configured for transporting a plurality of carriers with electrostatic chucks simultaneously into the chamber enclosure, and wherein the chamber enclosure is configured for plasma processing a plurality of substrates positioned on the plurality of electrostatic chucks simultaneously.

19. A method for fabricating an electrostatic chuck, comprising:
machining an aluminum chuck body having a top surface for accepting a substrate;
anodizing at least the top surface of the aluminum chuck body;
forming a ceramic layer on all sides of the aluminum chuck body; and,
forming an electrical contact to the aluminum body.

20. The method of claim 19, wherein the step of forming a ceramic layer comprises coating the sides of the aluminum chuck body with ceramic material.

21. The method of claim 19, wherein the step of forming a ceramic layer comprises fabricating a ceramic frame and bonding the aluminum chuck body to the ceramic frame.

22. The method of claim 21, wherein the ceramic frame is fabricated integrally with a ceramic plate to thereby form a tub, and wherein the aluminum body is bonded inside the tub, and further comprising forming an insulating plate and bonding the insulating plate to bottom surface of the tub.

23. The method of claim 22, further comprising forming a base and attaching the base to bottom surface of the insulating plate.
